(19) United States
(12) Patent Application Publication
(10) Pub. No.: US 2025/0309850 A1
(43) Pub. Date: Oct. 2, 2025

(54) COIL COMPONENT AND FILTER CIRCUIT INCLUDING THE SAME

(71) Applicant: Murata Manufacturing Co., Ltd., Nagaokakyo-shi (JP)

(72) Inventor: Atsushi TOUJO, Nagaokakyo-shi (JP)

(21) Appl. No.: 19/217,183

(22) Filed: May 23, 2025

Related U.S. Application Data
(63) Continuation of application No. PCT/JP2023/034859, filed on Sep. 26, 2023.

(30) Foreign Application Priority Data
Jan. 19, 2023 (JP) 2023-006740

(51) Int. Cl. H03H 1/00; H01F 5/04; H01F 27/29

(52) U.S. Cl. CPC H03H 1/00; H01F 5/04; H01F 27/292; H03H 2001/0092

(57) ABSTRACT

A coil component includes a housing including first and second main surfaces facing each other, and four side surfaces that join the main surfaces, a first coil inside the housing, and a second coil inside the housing with an opening thereof overlapping an opening of the first coil when viewed in a direction of the first main surface. A first extended line extends in a direction toward the second main surface along a side of the first side surface. A second extended line extends in the direction toward the second main surface along a side of the second side surface.

### CROSS REFERENCE TO RELATED APPLICATIONS

This application claims the benefit of priority to Japanese Patent Application No. 2023-006740 filed on Jan. 19, 2023 and is a Continuation Application of PCT Application No. PCT/JP2023/034859 filed on Sep. 26, 2023. The entire contents of each application are hereby incorporated herein by reference.

### BACKGROUND OF THE INVENTION

### 1. Field of the Invention

The present disclosure relates to coil components and filter circuits including the coil components.

### 2. Description of the Related Art

Noise control measures using a filter circuit are often performed in an electronic device. Examples of the filter circuit used for performing noise control measures include an electro-magnetic interference (EMI) removal filter, which passes necessary components in a current flowing through a conductor while removing unnecessary components. It is known that, since the filter circuit uses a capacitor, which is a capacitance element, a noise suppression effect is reduced due to an equivalent series inductance (ESL), which is a parasitic inductance of the capacitor.

A technique of cancelling the equivalent series inductance ESL of the capacitor by a negative inductance generated by magnetically coupling two coils to thereby broaden the band of the noise suppression effect of the filter circuit is known (for example, Japanese Unexamined Patent Application Publication No. 2001-160728). Further, a coil component having a structure in which two coils formed by bending a metal plate are provided so as to vertically overlap each other is known (for example, Japanese Unexamined Patent Application Publication No. 2004-296630).

### SUMMARY OF THE INVENTION

When a coil component having the structure described in Japanese Unexamined Patent Application Publication No. 2004-296630 is used in a filter circuit, the coil component is used as a three-terminal transformer coil in which a portion that connects two coils is used as an intermediate terminal. When the coil component is used as a three-terminal transformer coil, it is necessary to extend a wiring line from the intermediate terminal to a mounting surface, so that a positive parasitic inductance is generated in the wiring line. When such a coil component is used in a filter circuit, there will be a problem that a portion of the negative inductance generated by magnetically coupling the two coils will be canceled by the positive parasitic inductance generated in the wiring line, so that the negative inductance of the coil component is reduced.

Therefore, example embodiments of the present invention provide coil components each including a structure which does not reduce the negative inductance generated by magnetically coupling two coils, and filter circuits including the coil components.

A coil component according to an example embodiment of the present disclosure includes a housing including a pair of first and second main surfaces facing each other, and four side surfaces that join the first main surface and the second main surface, a first coil inside the housing and parallel or substantially parallel to the first main surface, and a second coil inside the housing with an opening thereof overlapping an opening of the first coil when viewed in a direction of the first main surface, wherein the first coil is connected to a first extended line and a second extended line that are extended from a first side surface side of the housing, the second coil is connected to a third extended line and a fourth extended line that are extended from a second side surface side different from the first side surface side, the second extended line extends in a direction toward the second main surface along the first side surface side, and the fourth extended line extends in the direction toward the second main surface along the second side surface side.

A filter circuit according to another embodiment of the present disclosure includes a coil component according to an example embodiment of the present disclosure, and a capacitor electrically connected to the second extended line and the fourth extended line of the coil component.

According to an example embodiment of the present disclosure, since the second extended line of the first coil extends in the direction toward the second main surface along the first side surface side, from which the second extended line is extended, and the fourth extended line of the second coil extends in the direction toward the second main surface along the second side surface side, from which the fourth extended line is extended, it is possible to provided a coil with the second extended line and the fourth extended line, so that the negative inductance generated by magnetically coupling two coils is not reduced.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view of a coil component according to Example Embodiment 1 of the present invention.

FIG. 2 is a circuit diagram of a filter circuit including the coil component according to Example Embodiment 1 of the present invention.

FIGS. 3A and 3B include views for explaining the change of the mutual inductance depending on the shape of an intermediate terminal.

FIGS. 4A to 4D include views for explaining the change of the mutual inductance depending on the shape of a housing.

FIG. 5 is a perspective view of a coil component according to Example Embodiment 2 of the present invention.

FIGS. 6A and 6B include views for explaining the positional relationship between opening surfaces of coils.

FIG. 7 is a perspective view of a coil component according to Modification 1 of an example embodiment of the present invention.

FIG. 8 is a perspective view of a coil component according to Modification 2 of an example embodiment of the present invention.

FIG. 9 is a view for explaining the positional relationship between opening surfaces of coils according to Modification 2 of an example embodiment of the present invention.

FIGS. 10A to 10J are exploded plan views showing a configuration of a coil component according to Modification 3 of an example embodiment of the present invention.

### DETAILED DESCRIPTION OF THE EXAMPLE EMBODIMENTS

Coil components according to example embodiments and filter circuits including the coil components will be described below with reference to the drawings.

### Example Embodiment 1

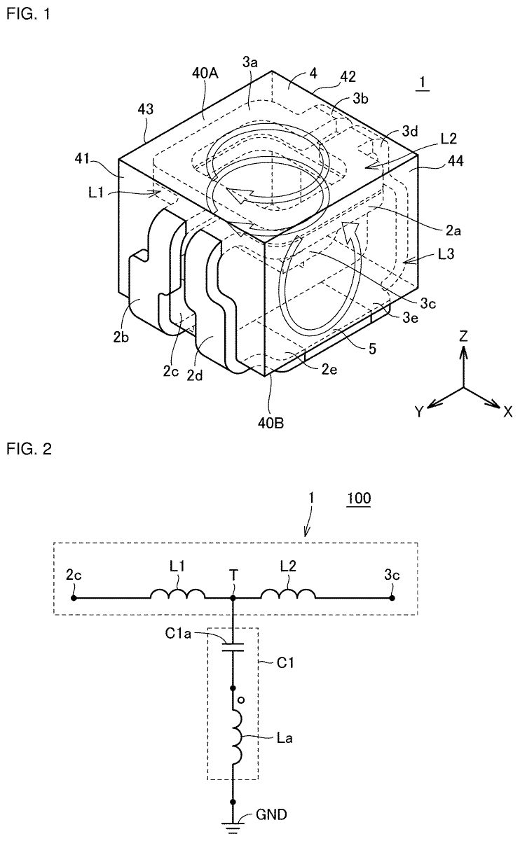

First, a coil component according to Example Embodiment 1 will be described with reference to the drawings. FIG. 1 is a perspective view of a coil component 1 according to Example Embodiment 1. FIG. 2 is a circuit diagram of a filter circuit 100 including the coil component 1 according to Example Embodiment 1. With respect to the X-axis, Y-axis, and Z-axis defined in FIG. 1, the X-axis direction represents a left-right direction of the coil component 1, the Y-axis direction represents a front-back direction of the coil component 1, and the Z-axis direction represents an up-down direction of the coil component 1.

The coil component 1 is a transformer coil mounted on the filter circuit 100 that is used to, for example, perform a noise control measure in a power supply line. As will be described later, in the coil component 1, two coils are magnetically coupled to cancel a parasitic inductance of a capacitor mounted on the filter circuit 100. Further, in the coil component 1, a structure is adopted in which a third coil includes extended lines of the two coils.

The coil component 1 includes a coil portion 2a (first coil) and a coil portion 3a (second coil) in a housing 4. Hereinafter, the coil portion 2a is also referred to as a coil L1, and the coil portion 3a is also referred to as a coil L2. The coil portion 2a includes an extended line 2b (first extended line) connected to one end thereof and an extended line 2d (second extended line) connected to the other end thereof. The coil portion 3a includes an extended line 3b (third extended line) connected to one end thereof and an extended line 3d (fourth extended line) connected to the other end thereof. The coil portion 2a and the extended lines 2b and 2d include a single conductor such as a metal plate or metal wire made of copper or an alloy obtained by mixing copper with other metal(s). Similarly, the coil portion 3a and the extended lines 3b and 3d include a single conductor. The coil L1 and the coil L2 including the metal plate are covered with an insulator material (not shown). Specifically, the insulator material covering the coil L1 and the coil L2 is a resin such as polyimide, epoxy, or the like. Note that the insulator material need not cover all surfaces of the coil L1 and the coil L2. It is sufficient if the insulating material is provided on at least the surfaces where the coil L1 and the coil L2 face each other to prevent contact between the coil L1 and the coil L2.

The coil portion 2a has a rectangular or substantially rectangular opening, and is positioned inside the housing 4 so as to be parallel or substantially parallel to a main surface 40A (first main surface). The coil portion 2a is illustrated as a single-turn coil, but it may also be a multi-turn coil. The extended line 2b and the extended line 2d are extended from a side surface 41 (first side surface) of the housing 4, and extend in the direction toward a main surface 40B (second main surface) along the side surface 41. The extended line 2b shown in FIG. 1 is provided up to the main surface 40B, and a portion of the extended line 2b in contact with the main surface 40B defines an end portion 2c. The extended line 2d is provided up to the main surface 40B, and a portion of the extended line 2d in contact with the main surface 40B defines an end portion 2e. When the coil component 1 is mounted on a substrate, the end portion 2c is electrically connected to a wiring line provided on the substrate.

The coil portion 3a includes a rectangular or substantially rectangular opening, and is located inside the housing 4, at a position above the coil portion 2a, so as to be parallel or substantially parallel to the main surface 40A. The coil portion 3a is illustrated as a single-turn coil, but it may also be a multi-turn coil. The extended line 3b and the extended line 3d are extended from a side surface 42 (second side surface) of the housing 4, and extend in the direction toward the main surface 40B along the side surface 42. The extended line 3b shown in FIG. 1 is provided up to the main surface 40B, and a portion of the extended line 3b in contact with the main surface 40B defines an end portion 3c. The extended line 3d is provided up to the main surface 40B, and a portion of the extended line 3d in contact with the main surface 40B defines an end portion 3e. When the coil component 1 is mounted on the substrate, the end portion 3c is electrically connected to a wiring line provided on the substrate. The end portion 2e and the end portion 3e are electrically connected by a connector 5 on the main surface 40B. The coil L1 and the coil L2 are connected in series by connecting the end portion 2e and the end portion 3e by the connector 5, and the end portions 2e and 3e and the connector 5 define an intermediate terminal T between the coil L1 and the coil L2.

The coil L1 and the coil L2 are located inside the housing 4 at positions closer to the main surface 40A than to the main surface 40B. Preferably, the coil L1 and the coil L2 are located at positions closer to the main surface 40A side than to an intermediate position located between the main surface 40A and the main surface 40B. Therefore, the length of the extended line 2d extending from the other end of the coil portion 2a to the main surface 40B and the length of the extended line 3d extending from the other end of the coil portion 3a to the main surface 40B can be increased, so that the opening of a coil (coil L3) including the extended line 2d, the extended line 3d and the connector 5 can be increased.

When the end portion 2c is connected to a power source, a current flows clockwise from the extended line 2b through the coil portion 2a (coil L1). The current flowing through the coil portion 2a flows counterclockwise through the extended line 2d, the connector 5, and the extended line 3d in this order. The current flows clockwise from the extended line 3d through the coil portion 3a (coil L2). Therefore, a magnetic field is generated in the coil portion 2a in a direction from the main surface 40A to the main surface 40B (−Z direction). Further, a magnetic field is generated in the coil portion 3a in a direction from the main surface 40A to the main surface 40B (−Z direction). Since the coil portion 2a and the coil portion 3a overlap with each other when viewed in the direction of the main surface 40A, the coil L1 and the coil L2 are magnetically coupled. A magnetic field in a +X direction is generated in the coil (coil L3) including the extended line 2d, the extended line 3d and the connector 5. Although FIG. 1 shows an example in which the openings substantially overlap with each other, the respective openings may alternatively be offset from each other within a range where the magnetic fields are coupled, as long as about 50% or more of one opening overlaps the other opening, for example.

The housing 4 fixes the relative position of the coil L1 and the coil L2, and is made of a molded resin, for example. Specifically, the molded resin is made of epoxy resin, silicone resin, or liquid crystal polymer, each added with silica filler, or made of various resins mixed with a metallic magnetic material. In the housing 4, the side surface 41 (first side surface) and the side surface 42 (second side surface) face each other, a side surface close to the extended line 2b (first extended line) is defined as a side surface 43 (third side surface), and a side surface close to the extended line 2d (second extended line) is defined as a side surface 44 (fourth side surface). FIG. 1 shows an example in which the housing 4 has a rectangular or substantially rectangular parallelepiped shape. However, the side surfaces may be inclined as long as the second main surface, which is the mounting surface, is parallel or substantially parallel to the coil surface. For example, the housing 4 may have a trapezoidal shape in which the area of the second main surface is greater than the area of the first main surface.

The filter circuit 100 is, for example, an EMI removal filter as shown in FIG. 2, and is a third-order T-shaped LC filter circuit. In the filter circuit 100, the end portion 2c is connected to a power supply (not shown), and the end portion 3c is connected to a circuit (not shown) such as a DC/DC converter or a power supply module. The filter circuit 100 passes necessary components contained in the current flowing from the power supply to the circuit and removes unnecessary components. Specifically, a DC current is passed through the filter circuit 100, and high-frequency noise contained in the DC current is dropped to the GND through a capacitor C1. Since the capacitor C1, which is a capacitance element, has an equivalent series inductance ESL (La) of the capacitor C1, the passage of the high-frequency noise is blocked, so that noise removal performance deteriorates. The filter circuit 100 cancels the ESL (La) of the capacitor C1 by using a negative inductance generated by magnetically coupling the two coils to maintain high noise removal performance. In the present disclosure, the negative inductance generated in series with respect to the capacitor C1 is referred to as a mutual inductance M of the coil component 1.

In the following example embodiment, a third-order T-shaped LC filter circuit is used as a configuration of the filter circuit 100, but the coil component of the same configuration may also be applied to a fifth-order T-shaped LC filter circuit or a higher-order T-shaped LC filter circuit. As shown in FIG. 2, the filter circuit 100 includes the capacitor C1, the end portions 2c and 3c, the intermediate terminal T (the end portions 2e and 3e, and the connector 5), the coil L1, and the coil L2.

As shown in FIG. 2, the capacitor C1 has one end portion thereof connected to the intermediate terminal T, and the other end portion thereof connected to a GND line. Note that the capacitor C1 may be not only a multilayer ceramic capacitor made of BaTiO₃ (barium titanate) as a main component, but also a multilayer ceramic capacitor made of another material as a main component. Also, the capacitor C1 may also be another type of capacitor, such as an aluminum electrolytic capacitor, instead of a multilayer ceramic capacitor. The capacitor C1 has an inductor La as a parasitic inductance (equivalent series inductance (ESL)), and is equivalent to a circuit configuration in which the inductor La is connected in series to a capacitor C1a. Note that the capacitor C1 may also be equivalent to a circuit configuration in which a parasitic resistance (equivalent series resistance (ESR)) is connected in series to the inductor La and the capacitor C1a.

In addition to the capacitor C1, the coil L1 and the coil L2 are connected to the intermediate terminal T. The coil L1 and the coil L2 are magnetically coupled to have the mutual inductance M. A negative inductance component of the same magnitude as the mutual inductance M is generated between the intermediate terminal T and the capacitor C1. By using such a negative inductance component, the parasitic inductance (inductor La) of the capacitor C1 can be canceled, so that the parasitic inductance component of the capacitor C1 can be reduced in appearance. In other words, the filter circuit 100 including the capacitor C1, the coil L1, and the coil L2 cancels the parasitic inductance of the capacitor C1 by using the negative inductance component due to the mutual inductance of the coils L1 and L2, thereby suppressing the reduction of the noise suppression effect in the high-frequency band due to the parasitic inductance of the capacitor C1, so that the noise suppression effect of the filter circuit 100 can be improved.

However, in the case of a three-terminal coil component in which a portion for connecting the coil L1 and the coil L2 is used as the intermediate terminal T, if a wiring line is extended from the intermediate terminal T to be connected to the capacitor C1, a positive parasitic inductance will be generated in the wiring line. When such a coil component is used in a filter circuit, the negative inductance component due to the mutual inductance between the coil L1 and the coil L2 will be reduced by the positive parasitic inductance generated in the wiring line, so that the parasitic inductance of the capacitor C1 cannot be sufficiently canceled, thus reducing the noise suppression effect in the high-frequency band.

Therefore, in the coil component 1 according to Example Embodiment 1, instead of simply extending a wiring line from the intermediate terminal T, which connects the coils L1 and L2, and connecting the wiring line to the capacitor C1, a coil (coil L3) includes the extended line 2d, the extended line 3d, and the connector 5 and is connected to the capacitor C1 as shown in FIG. 1. Specifically, the connector 5 is electrically connected to a wiring line provided on the substrate, and connected to the capacitor C1, which is electrically connected to the same wiring line. In the coil component 1, since the coil L3 itself connected to the capacitor C1 is also coupled as a part of the coil L1 and the coil L2, it contributes to the negative inductance component due to the mutual inductance between the coil L1 and the coil L2, so that the negative inductance component does not decrease. The component connected to the wiring line provided on the substrate may alternatively be the end portion 2e connected to the extended line 2d and the end portion 3e connected to the extended line 3d, instead of being the connector 5.

Further, since the intermediate terminal T connecting the coil L1 and the coil L2 is the coil (coil L3) including the extended line 2d, the extended line 3d, and the connector 5, the three coils L1 to L3 are in a relationship such that they have a positive coupling coefficient. It has been explained in the above description that in the coil component 1, the connector 5 is on the main surface 40B. However, the connector 5 may alternatively be provided on the side of the substrate, on which the coil component 1 is to be mounted. In other words, the coil component 1 itself does not define the coil (coil L3) since the extended line 2d and the extended line 3d are not electrically connected to each other, but the coil (coil L3) can be provided by mounting the coil component 1 on the substrate provided with the connector 5. Even if the coil component 1 is not provided with the connector 5, by mounting the coil component 1 on the substrate provided with the connector 5, it is not necessary to extend a wiring line from the intermediate terminal T and connect it to the capacitor C1. Therefore, the negative inductance component due to the mutual inductance between the coil L1 and the coil L2 is not reduced by the wiring line.

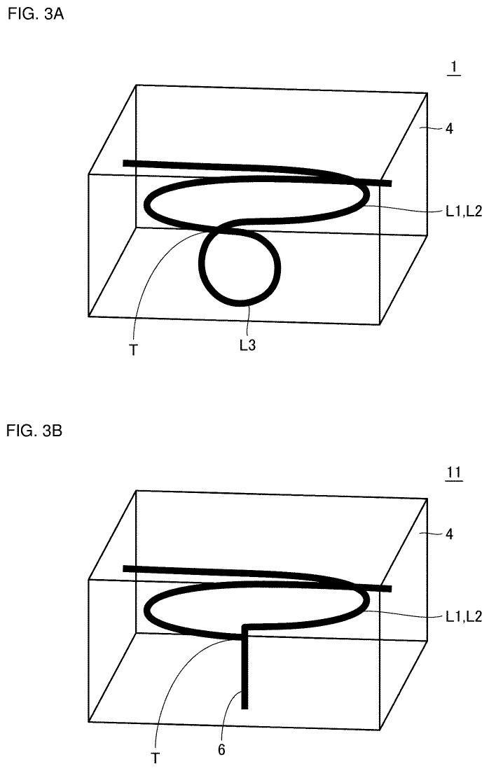

FIGS. 3A and 3B include views for explaining the change of the mutual inductance depending on the shape of the intermediate terminal. FIG. 3A is a view that schematically shows the shape of the intermediate terminal of the coil component 1. In FIG. 3A, since the shape of the intermediate terminal T connected to the capacitor C1 (not shown) is the coil L3, the inductance component of the coil L3 is added to the transformer coil including the coil L1 and the coil L2. Therefore, the mutual inductance M of the coil component 1 becomes high. Specifically, when the size of the coil component 1 is about 2.5×2.0×1.5 mm and the inductance value of the coil L1 and the coil L2 is about 3 nH, the simulation value of the mutual inductance M of the coil component 1 is M=about −1.024 nH, for example.

On the other hand, FIG. 3B is a view that schematically shows a configuration in which a wiring line 6 is extended from the intermediate terminal T and connected to the capacitor C1 (not shown) in a coil component 11 as a comparison. In FIG. 3B, since the wiring line 6 for connection to the capacitor C1 has a positive parasitic inductance, such a positive parasitic inductance is offset by the mutual inductance M between the coil L1 and the coil L2, so that the mutual inductance M of the coil component 11 becomes low. Specifically, when the coil component 11 has the same inductance value of the coil L1 and the coil L2 as those of the coil component 1 shown in FIG. 3A and the length of the wiring line 6 of the coil component 11 is about 1.0 mm, the simulation value of the mutual inductance M of the coil component 11 is M=about −0.24 nH, for example.

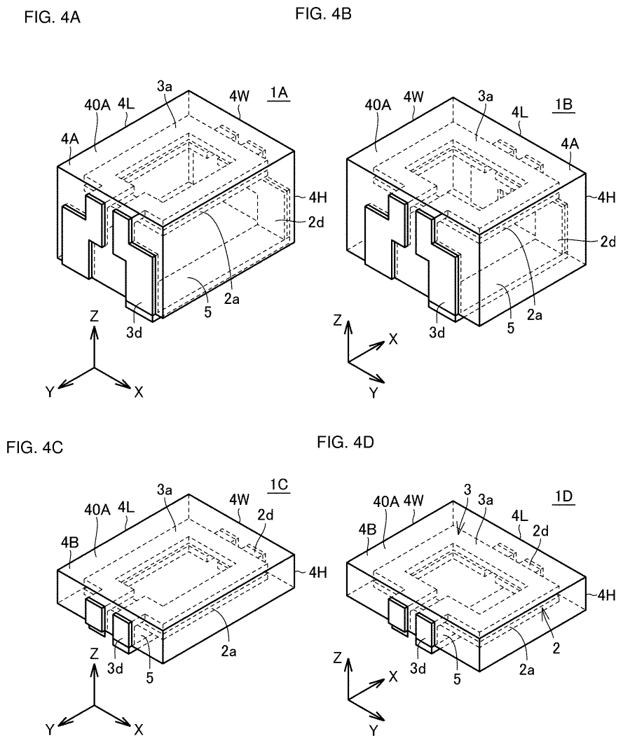

Since the size of the opening of the coil L3 changes depending on the shape of the housing 4, the mutual inductance M of the coil component also changes. FIGS. 4A to 4D includes views for explaining the change of the mutual inductance M depending on the shape of the housing. FIG. 4A is a perspective view of a coil component 1A in which the coils L1 and L2 are enclosed in a housing 4A in which the main surface 40A is a rectangle having long sides 4L and short sides 4W. In the coil component 1A, the extended lines 2b and 2d and the extended lines 3b and 3d are extended from the side surfaces on the short sides 4W side. Therefore, in the coil component 1A, a side surface on the long sides 4L side is the opening of the coil L3. Specifically, when the housing 4A has the long side 4L=about 2.5 mm, the short side 4W=about 2.0 mm, and the height 4H=about 1.5 mm, and the distance between the coil L1 and the coil L2 is about 0.02 mm, the simulation value of the mutual inductance M of the coil component 1A is M=about −1.12 nH, for example.

FIG. 4B is a perspective view of a coil component 1B in which the extended lines 2b and 2d and the extended lines 3b and 3d are extended from the side surfaces on the long sides 4L side of the housing 4A. In the coil component 1B, the extended lines 2b and 2d and the extended lines 3b and 3d are extended from the side surfaces on the long sides 4L side. Therefore, in the coil component 1B, a side surface on the short sides 4W side is the opening of the coil L3. Specifically, since the opening of the coil L3 of the coil component 1B is smaller than that of the coil component 1A, the simulation value of the mutual inductance M of the coil component 1B is M=about −1.06 nH, for example. The size and the distance between the coil L1 and the coil L2 of the coil component 1B are the same as those of the coil component 1A shown in FIG. 4A.

FIG. 4C is a perspective view of a coil component 1C in which the coils L1 and L2 are enclosed in a housing 4B whose height 4H is smaller than that of the housing 4A. In the coil component 1C, the extended lines 2b and 2d and the extended lines 3b and 3d are extended from the side surfaces on the short sides 4W side. Therefore, in the coil component 1C, a side surface on the long sides 4L side is the opening of the coil L3. Specifically, when the housing 4B has the long side 4L=about 2.5 mm, the short side 4W=about 2.0 mm, and the height 4H=about 0.9 mm, and the distance between the coil L1 and the coil L2 is about 0.02 mm, the simulation value of the mutual inductance M of the coil component 1C is M=about −0.81 nH, for example.

FIG. 4D are perspective views of a coil component 1D in which the extended lines 2b and 2d and the extended lines 3b and 3d are extended from the side surfaces on the long sides 4L side of the housing 4B. In the coil component 1D, the extended lines 2b and 2d and the extended lines 3b and 3d are extended from the side surfaces on the long sides 4L side. Therefore, in the coil component 1D, a side surface on the short sides 4W side is the opening of the coil L3. Specifically, although the opening of the coil L3 of the coil component 1D is smaller than that of the coil component 1C, since the height 4H is smaller than that of the coil component 1C, the influence on the mutual inductance M is small, so that the simulation value of the mutual inductance M of the coil component 1D is M=−0.81 nH. The size and the distance between the coil L1 and the coil L2 of the coil component 1D are the same as those of the coil component 1C shown in FIG. 4C.

As described above, the coil component 1 according to Example Embodiment 1 includes a housing 4 including a pair of main surfaces 40A and 40B facing each other and four side surfaces 41 to 44 that join the main surface 40A and the main surface 40B, a coil L1 inside the housing 4 so as to be parallel or substantially parallel to the main surface 40A, and a coil L2 inside the housing 4 with an opening of the coil L2 overlapping an opening of the coil L1 when viewed in the direction of the main surface 40A. The coil L1 includes an extended line 2b and an extended line 2d that are extended from the side surface 41 side of the housing 4. The coil L2 includes an extended line 3b and an extended line 3d that are extended from the side surface 42 side different from the side surface 41. The extended line 2d extends in the direction toward the main surface 40B along the side surface 41 side. The extended line 3d extends in the direction toward the main surface 40B along the side surface 42 side. Note that, in the present description, the expression “extend along a side surface side” means extending parallel or substantially parallel to the side surface.

With such a configuration, in the coil component 1 according to Example Embodiment 1, since the extended line 2d of the coil L1 extends in the direction toward the main surface 40B along the side surface 41 side, from which the extended line 2d is extended, and the extended line 3d of the coil L2 extends in the direction toward the main surface 40B along the side surface 42 side, from which the extended line 3d is extended, the extended line 2d and the extended line 3d can define a coil, and the negative inductance generated by magnetically coupling the two coils L1 and L2 does not decrease. In particular, since the extended line 2d and the extended line 3d are provided along the side surface 41 and the side surface 42 facing each other, respectively, the opening of the coil L3 can be increased and the value of the mutual inductance M can be increased without changing the size of the housing.

In the coil component 1, the extended line 2b and the extended line 2d are extended from the side surface 41 side to the outside of the housing 4. However, in the coil component 1, the extended line 2b and the extended line 2d do not have to be extended to the outside of the housing 4 but may alternatively be provided inside the housing 4 as long as the extended line 2b and the extended line 2d are extended to the side surface 41 side. Similarly, in the coil component 1, the extended line 3b and the extended line 3d are extended from the side surface 42 side to the outside of the housing 4. However, in the coil component 1, the extended line 3b and the extended line 3d do not have to be extended to the outside of the housing 4 but may alternatively be provided inside the housing 4 as long as the extended line 3b and the extended line 3d are extended to the side surface 42 side.

The filter circuit 100 according to Example Embodiment 1 includes the coil component 1 and the capacitor C1 electrically connected to the intermediate terminal (the extended line 2d, the extended line 3d) between the coils L1 and L2 of the coil component 1. With such a configuration, the filter circuit 100 can sufficiently cancel the parasitic inductance of the capacitor C1 with the negative inductance generated by magnetically coupling the two coils L1 and L2, thus broadening the band of the noise suppression effect.

### Example Embodiment 2

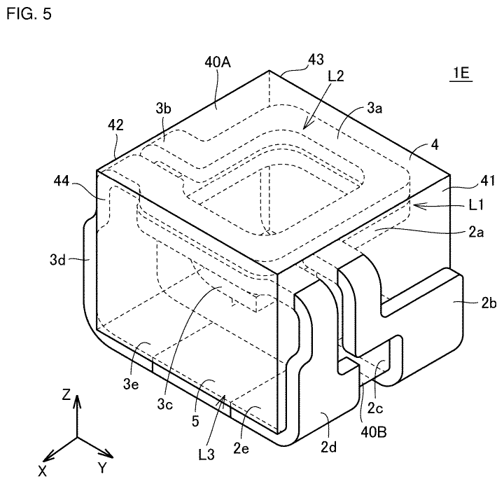

In Example Embodiment 1, it has been explained that the coil (coil L3) includes the extended line 2d, the extended line 3d, and the connector 5 of the coil component 1. In Example Embodiment 2, the direction of the opening surface of the coil (coil L3) will be described in detail. FIG. 5 is a perspective view of a coil component 1E according to Example Embodiment 2. Note that in the coil component 1E according to Example Embodiment 2, the same configurations as those of the coil component 1 according to Example Embodiment 1 are denoted by the same reference signs, and the detailed descriptions thereof will not be repeated. Also, the coil component 1E according to Example Embodiment 2 can be applied to the filter circuit 100 according to Example Embodiment 1, instead of the coil component 1 according to Example Embodiment 1.

As shown in FIG. 5, the extended line 2d and the extended line 3d of the coil component 1E extend straight or substantially straight from the positions where they are extended toward the main surface 40B side. Therefore, the opening surface of the coil (coil L3) including the extended line 2d, the extended line 3d, and the connector 5 is perpendicular (at 90 degrees) to the opening surfaces of the coil L1 and the coil L2.

The side surface 41 (first side surface) and the side surface 42 (second side surface) of the housing 4 face each other, and a side surface close to the extended line 2b (first extended line) is defined as a side surface 43 (third side surface), and a side surface close to the extended line 2d (second extended line) is defined as a side surface 44 (fourth side surface). The extended line 2b and the extended line 2d are extended from the side surface 41 on the side surface 44 side. The extended line 3b and the extended line 3d are extended from the side surface 42 on the side surface 44 side. In other words, the coil component 1E is enclosed in the housing 4 in a state in which the positions where the extended line 2b, the extended line 2d, the extended line 3b, and the extended line 3d are extended from the coil portions 2a and 3a are located closer to the side surface 44 side. Here, the expression “a state in which the extended line 2b and the extended line 2d are located closer to the side surface 44 side” means that a region between the connection point of the coil portion 2a and the extended line 2b and the connection point of the coil portion 2a and the extended line 2d is located closer to the side surface 44 side than to the intermediate position between the side surface 43 and the side surface 44.

Further, the end portion of the extended line 2d on the main surface 40B side is on the side surface 41 on the side surface 44 side. Specifically, the extended line 2d is extended from a position within the width of the end portion 2e when viewed in the direction in which the end portion 2e, the end portion 3e, and the connector extend (Y-axis direction). The end portion of the extended line 3d on the main surface 40B side is on the side surface 42 on the side surface 44 side. Specifically, the extended line 3d is extended from a position within the width of the end portion 3e when viewed in the Y-axis direction. In other words, the extended line 2d and the extended line 3d are straight or substantially straight lines extending from the positions where they are extended toward the main surface 40B side. Therefore, the coil (coil L3) including the extended line 2d, the extended line 3d and the connector 5 is parallel or substantially parallel to the side surface 44.

On the other hand, as shown in FIG. 1, in the coil component 1, the extended line 2b and the extended line 2d are extended from an intermediate portion of the side surface 41 located between the side surface 43 and the side surface 44, and the extended line 3b and the extended line 3d are extended from an intermediate portion of the side surface 42 located between the side surface 43 and the side surface 44. In other words, in the coil component 1, the coil portions 2a and 3a are enclosed in the housing 4 at an intermediate position located between the side surface 43 and the side surface 44, and the extended line 2b, the extended line 2d, the extended line 3b, and the extended line 3d are also extended from the intermediate portions of the side surfaces located between the side surface 43 and the side surface 44. Here, the expression “extended from the intermediate portion” means that a certain point in a region between the connection point of the coil portion 2a and the extended line 2b and the connection point of the coil portion 2a and the extended line 2d overlaps the intermediate position located between the side surface 43 and the side surface 44.

Further, the end portion of the extended line 2d on the main surface 40B side is on the side surface 41 on the side surface 44 side. The end portion of the extended line 3d on the main surface 40B side is on the side surface 42 on the side surface 44 side. In other words, the extended line 2d and the extended line 3d extend, in a direction oblique from the positions where they are extended to the side surface 44 side, toward the main surface 40B side. Therefore, the coil (coil L3) including the extended line 2d, the extended line 3d, and the connector 5 is inclined with respect to the side surface 44. The opening surface of the coil L3 is inclined at an angle greater than about 90 degrees with respect to the opening surfaces of the coil L1 and the coil L2, for example.

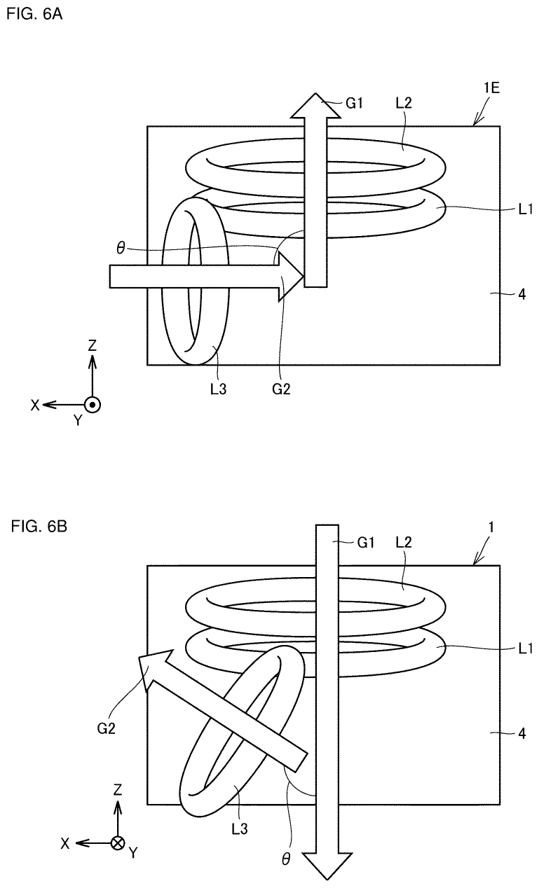

The positional relationship between the opening surface of the coil L3 and the opening surfaces of the coil L1 and the coil L2 is described with reference to schematic views so that such a positional relationship can be easily understood. FIGS. 6A and 6B include views for explaining the positional relationship between the opening surfaces of the coils. FIG. 6A is a schematic view showing the positional relationship between the opening surface of the coil L3 and the opening surfaces of the coil L1 and the coil L2 of the coil component 1E. In the coil component 1E, the coil L1 and the coil L2 are parallel or substantially parallel to the X-Y plane, and the coil L3 is parallel or substantially parallel to the Y-Z plane. In the coil component 1E, the angle e between the direction of a magnetic field G1 generated by the coil L1 and the coil L2 and the direction of a magnetic field G2 generated by the coil L3 is about 90 degrees, for example.

On the other hand, FIG. 6B is a schematic view showing the positional relationship between the opening surface of the coil L3 and the opening surfaces of the coil L1 and the coil L2 of the coil component 1. In the coil component 1, the coil L1 and the coil L2 are parallel or substantially parallel to the X-Y plane, and the coil L3 is inclined from a position parallel or substantially parallel to the Y-Z plane to the X direction. In the coil component 1, the angle θ between the direction of the magnetic field G1 generated by the coil L1 and the coil L2 and the direction of the magnetic field G2 generated by the coil L3 is greater than about 90 degrees, for example.

When the angle θ between the direction of the magnetic field G1 and the direction of the magnetic field G2 is greater than about 90 degrees, for example, as in the coil component 1, the direction of the magnetic field G2 includes a component opposite to the direction of the magnetic field G1, so that the coupling coefficient of the three coils L1 to L3 is reduced. Therefore, by making the angle θ between the direction of the magnetic field G1 and the direction of the magnetic field G2 equal to about 90 degrees, for example, as in the coil component 1E, the direction component opposite to the direction of the magnetic field G1 is reduced in the direction of the magnetic field G2, so that the coupling coefficient of the three coils L1 to L3 can be increased. In the coil component 1E, increasing the coupling coefficient of the three coils L1 to L3 contributes to the negative inductance component due to the mutual inductance between the coils L1 and L2, so that the negative inductance component is not reduced.

### Modification 1

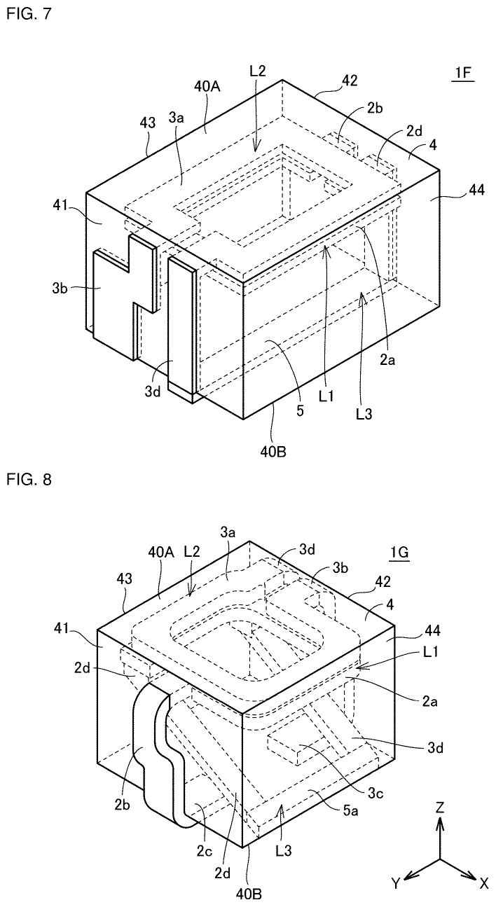

In the coil component 1E, as shown in FIG. 5, by enclosing the coil portions 2a and 3a in the housing 4 and bringing the coil portions 2a and 3a closer to the side surface 44 side, the coil L3 is positioned so that the angle θ between the direction of the magnetic field G1 and the direction of the magnetic field G2 becomes 90 degrees. However, the coil L3 can be positioned so that the angle θ between the direction of the magnetic field G1 and the direction of the magnetic field G2 is 90 degrees without bringing the coil portions 2a and 3a closer to the side surface 44 side. FIG. 7 is a perspective view of a coil component 1F according to Modification 1. Note that in the coil component 1F according to Modification 1, the same configurations as those of the coil component 1 according to Example Embodiment 1 are denoted by the same reference signs, and the detailed descriptions thereof will not be repeated. Also, the coil component 1F according to Modification 1 can be applied to the filter circuit 100 according to Example Embodiment 1, instead of the coil component 1 according to Example Embodiment 1.

As shown in FIG. 7, the extended line 2d and the extended line 3d of the coil component 1F extend straight from the positions where they are extended toward the main surface 40B side. Therefore, the opening surface of the coil (coil L3) including the extended line 2d, the extended line 3d, and the connector 5 is perpendicular (at 90 degrees) to the opening surfaces of the coil L1 and the coil L2.

In the coil component 1F, as shown in FIG. 7, the extended line 2b and the extended line 2d are extended from an intermediate portion of the side surface 41 located between the side surface 43 and the side surface 44, and the extended line 3b and the extended line 3d are extended from an intermediate portion of the side surface 42 located between the side surface 43 and the side surface 44. In other words, in the coil component 1F, as in the coil component 1 shown in FIG. 1, the coil portions 2a and 3a are enclosed in the housing 4 at an intermediate position located between the side surface 43 and the side surface 44, and the extended line 2b, the extended line 2d, the extended line 3b and the extended line 3d are extended from the intermediate portions of the side surfaces located between the side surface 43 and the side surface 44.

Further, in the coil component 1F, the end portion of the extended line 2d on the main surface 40B side is located in the intermediate portion of the side surface 42 located between the side surface 43 and the side surface 44, and the end portion of the extended line 3d on the main surface 40B side is located in the intermediate portion of the side surface 41 located between the side surface 43 and the side surface 44. In other words, the extended line 2d and the extended line 3d are straight lines extending from the positions where they are extended toward the main surface 40B side. Therefore, the coil (coil L3) including the extended line 2d, the extended line 3d, and the connector 5 is parallel or substantially parallel to the side surface 44.

In the coil component 1F, the opening surface of the coil L3 is perpendicular or substantially perpendicular (e.g., about 90 degrees) to the opening surfaces of the coil L1 and the coil L2 at the central portions of the coil L1 and the coil L2. In the coil component 1E, on the other hand, as shown in FIG. 5, the opening surface of the coil L3 is perpendicular or substantially perpendicular (e.g., about 90 degrees) to the opening surfaces of the coil L1 and the coil L2 at the end portions of the coil L1 and the coil L2. Therefore, the coupling coefficient of the three coils L1 to L3 can be made higher in the coil component 1E than in the coil component 1F.

### Modification 2

In the coil component 1, as shown in FIG. 6A, the coil L3 is positioned so that the angle θ between the direction of the magnetic field G1 and the direction of the magnetic field G2 is greater than about 90 degrees, for example. In the coil component 1E, as shown in FIG. 6B, the coil L3 is positioned so that the angle θ between the direction of the magnetic field G1 and the direction of the magnetic field G2 is about 90 degrees, for example. In the coil component according to Modification 2, the coil L3 is positioned so that the angle θ between the direction of the magnetic field G1 and the direction of the magnetic field G2 is less than about 90 degrees, for example. FIG. 8 is a perspective view of a coil component 1G according to Modification 2. Note that in the coil component 1G according to Modification 2, the same configurations as those of the coil component 1 according to Example Embodiment 1 are denoted by the same reference signs, and the detailed descriptions thereof will not be repeated. Also, the coil component 1G according to Modification 2 can be applied to the filter circuit 100 according to Example Embodiment 1, instead of the coil component 1 according to Example Embodiment 1.

As shown in FIG. 8, the extended line 2d and the extended line 3d of the coil component 1G extend, in an oblique direction, from the positions where they are extended toward the main surface 40B side. Therefore, the opening surface of the coil (coil L3) including the extended line 2d, the extended line 3d, and the connector 5 is at an angle less than about 90 degrees with respect to the opening surfaces of the coil L1 and the coil L2, for example.

The extended line 2b is extended from the side surface 41 on the side surface 43 side. Since the extended line 2d is extended from a side closer to the side surface 43 side than the extended line 2b toward the side surface 44 side, the extended line 2d is extended through the inside of the housing 4. Similarly, the extended line 3b is extended from the side surface 42 on the side surface 43 side. Since the extended line 3d is extended from a side closer to the side surface 43 side than the extended line 3b toward the side surface 44 side, the extended line 3d is extended through the inside of the housing 4. In other words, the extended line 2b and the extended line 3b are extended to the outside of the housing 4, and the extended line 2d and the extended line 3d are extended to the inside of the housing 4. The extended line 2b and the extended line 2d cross each other in the middle, and the extended line 3b and the extended line 3d cross each other in the middle.

Further, the end portion of the extended line 2d on the main surface 40B side is on the side surface 41 side on the side surface 44 side. The end portion of the extended line 3d on the main surface 40B side is on the side surface 42 side on the side surface 44 side. In other words, the extended line 2d and the extended line 3d extend, in a direction oblique from the positions where they are extended to the side surface 44 side, toward the main surface 40B side. The end portion of the extended line 2d and the end portion of the extended line 3d are electrically connected via the connector 5a in the housing 4. Therefore, the coil (coil L3) including the extended line 2d, the extended line 3d, and the connector 5a is inclined with respect to the side surface 44. The opening surface of the coil L3 is inclined at an angle less than about 90 degrees with respect to the opening surfaces of the coil L1 and the coil L2, for example.

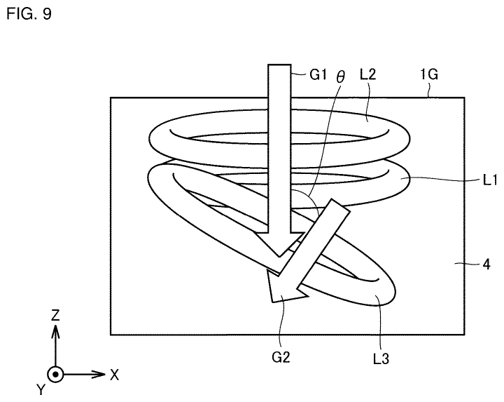

The positional relationship between the opening surface of the coil L3 and the opening surfaces of the coil L1 and the coil L2 is described with reference to a schematic view so that such a positional relationship can be easily understood. FIG. 9 is a view for explaining the positional relationship between the opening surfaces of the coil according to Modification 2. FIG. 9 is a schematic view showing the positional relationship between the opening surface of the coil L3 and the opening surfaces of the coil L1 and the coil L2 of the coil component 1G. In the coil component 1G, the coil L1 and the coil L2 are parallel or substantially parallel to the X-Y plane, and the coil L3 is inclined from a position parallel or substantially parallel to the Y-Z plane to the X direction. In the coil component 1G, the angle θ between the direction of the magnetic field G1 generated by the coil L1 and the coil L2 and the direction of the magnetic field G2 generated by the coil L3 is less than about 90 degrees, for example.

When the angle θ between the direction of the magnetic field G1 and the direction of the magnetic field G2 is less than about 90 degrees, for example, as in the coil component 1G, the direction of the magnetic field G2 includes a directional component in the same direction as the direction of the magnetic field G1, so that the coupling coefficient of the three coils L1 to L3 is increased. Therefore, by making the angle θ between the direction of the magnetic field G1 and the direction of the magnetic field G2 less than about 90 degrees, for example, as in the coil component 1G, the direction component in the same direction as the direction of the magnetic field G1 is increased in the direction of the magnetic field G2, so that the coupling coefficient of the three coils L1 to L3 can be increased.

### Modification 3

In the coil components according to the example embodiments and modifications described above, the coil portion 2a and the extended lines 2b and 2d include a single conductor (for example, a metal plate), and the coil portion 3a and the extended lines 3b and 3d include one conductor. Further, in such a coil component, the coil portion 2a and the coil portion 3a including a conductor are fixed with the mold resin of the housing 4 at a position where they overlap each other, and the extended lines 2b, 2d, 3b, and 3d extended from the side surfaces of the housing 4 are bent along the side surfaces of the housing 4. However, the method of manufacturing the coil component is not limited to the method described above. In Modification 3, a coil component that includes coils not including a single conductor and that is manufactured by laminating a plurality of substrates (ceramic green sheets) each including a coil wiring line thereon is described.

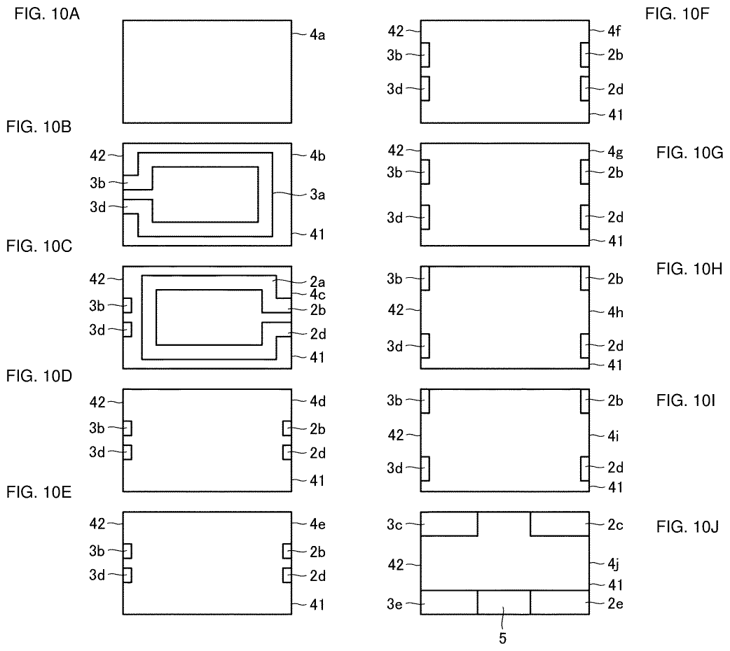

FIGS. 10A to 10J are exploded plan views showing a configuration of the coil component according to Modification 3. Note that in the coil component according to Modification 3, the same configurations as those of the coil component 1 according to Example Embodiment 1 are denoted by the same reference signs, and the detailed descriptions thereof will not be repeated. Also, the coil component according to Modification 3 can be applied to the filter circuit 100 according to Example Embodiment 1, instead of the coil component 1 according to Example Embodiment 1.

As shown in FIGS. 10A to 10J, the coil component according to Modification 3 includes a ceramic layered housing 4 obtained by laminating a plurality of substrates (ceramic green sheets) each including a coil wiring line thereon. In the coil component according to Modification 3, wiring patterns of the coils L1 and L2 are inside the housing 4. As shown in FIGS. 10A to 10J, the wiring patterns of the coils L1 and L2 are formed by applying a conductive paste (Ni paste) on ceramic green sheets 4a to 4j, which are substrates, by a screen printing method.

As shown in FIG. 10A, no wiring pattern is provided on the ceramic green sheet 4a. As shown in FIG. 10B, wiring patterns of the coil portion 3a and the extended lines 3b and 3d of the coil L2 are on the ceramic green sheet 4b. The wiring pattern of the coil portion 3a is positioned so as to go one lap around each side of the ceramic green sheet 4b. The wiring patterns of the extended lines 3b and 3d are extended from the coil portion 3a to the side surface 42 side of the ceramic green sheet 4b.

As shown in FIG. 10C, wiring patterns of the coil portion 2a and the extended lines 2b and 2d of the coil L1 are provided on the ceramic green sheet 4c. The wiring pattern of the coil portion 2a is arranged so as to go one lap around each side of the ceramic green sheet 4c. The wiring patterns of the extended lines 2b and 2d are extended from the coil portion 2a to the side surface 41 side of the ceramic green sheet 4c. The wiring patterns of the extended lines 3b and 3d are on the side surface 42 side of the ceramic green sheet 4c.

As shown in FIGS. 10D to 10I, on the ceramic green sheets 4d to 4i, wiring patterns of the extended lines 2b and 2d and wiring patterns of the extended lines 3b and 3d are on the side surface 41 side and the side surface 42 side, respectively.

As shown in FIG. 10J, wiring patterns of the end portions 2c, 2e, 3c, and 3e that define the end portions of the extended lines 2b, 2d, 3b, and 3d are on the ceramic green sheet 4j. The wiring patterns of the end portions 2c and 2e are on the side surface 41 side of the ceramic green sheet 4j, and the wiring patterns of the end portions 3c and 3e are on the side surface 42 side of the ceramic green sheet 4j. Further, a wiring pattern of the connector 5 connecting the end portion 2e and the end portion 3e is on the ceramic green sheet 4j.

In the coil component according to Modification 3, at least one of each of the plurality of ceramic green sheets 4a to 4j is laminated, and a plurality of ceramic green sheets on which wiring patterns are not printed (dummy layers) are laminated on the upper and lower sides of the at least one of each of the plurality of ceramic green sheets 4a to 4j. An unfired housing 4 (ceramic element) is formed by subjecting the plurality of ceramic green sheets including the dummy layers to pressure bonding. The housing 4 formed in the aforesaid manner is baked, and a copper electrode is baked on the outside of the baked housing 4 to form an electrode so as to be conductive to the wiring pattern.

As described above, the coil component according to Modification 3 can be manufactured by laminating a plurality of substrates (ceramic green sheets) on which wiring lines of the coils are formed, instead of being manufactured by fixing the coil L1 and the coil L2 including a metal plate with the mold resin of the housing 4.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A coil component comprising:
a housing including a pair of first and second main surfaces facing each other, and four side surfaces that join the first main surface and the second main surface;
a first coil inside the housing and parallel or substantially parallel to the first main surface; and
a second coil inside the housing with an opening thereof overlapping an opening of the first coil when viewed in a direction of the first main surface; wherein
the first coil is connected to a first extended line and a second extended line that are extended from a first side surface side of the housing;
the second coil is connected to a third extended line and a fourth extended line that are extended from a second side surface side different from the first side surface side;
the second extended line extends in a direction toward the second main surface along the first side surface side; and
the fourth extended line extends in the direction toward the second main surface along the second side surface side.

2. The coil component according to claim 1, wherein the first coil and the second coil are closer to the first main surface than to the second main surface inside the housing.

3. The coil component according to claim 2, wherein the first coil and the second coil are closer to the first main surface side than to an intermediate position located between the first main surface and the second main surface.

4. The coil component according to claim 1, wherein the second extended line and the fourth extended line extend up to the second main surface.

5. The coil component according to claim 1, further comprising a connector provided on the second main surface to electrically connect the second extended line and the fourth extended line.

6. The coil component according to claim 1, wherein
when the first side surface and the second side surface face each other, and a side surface closest to the first extended line is defined as a third side surface and a side surface closest to the second extended line is defined as a fourth side surface;
the first extended line and the second extended line are extended from an intermediate portion of the first side surface located between the third side surface and the fourth side surface; and
the third extended line and the fourth extended line are extended from an intermediate portion of the second side surface located between the third side surface and the fourth side surface.

7. The coil component according to claim 6, wherein
an end portion of the second extended line on the second main surface side is located in the intermediate portion of the first side surface located between the third side surface and the fourth side surface; and
an end portion of the fourth extended line on the second main surface side is located in the intermediate portion of the second side surface located between the third side surface and the fourth side surface.

8. The coil component according to claim 6, wherein
an end portion of the second extended line on the second main surface side is on the first side surface side on the fourth side surface side; and
an end portion of the fourth extended line on the second main surface side is on the second side surface side on the fourth side surface side.

9. The coil component according to claim 1, wherein
when the first side surface and the second side surface face each other, and a side surface closest to the first extended line is defined as a third side surface and a side surface closest to the second extended line is defined as a fourth side surface;
the first extended line and the second extended line are extended from the first side surface side on the fourth side surface side;
an end portion of the second extended line on the second main surface side is on the first side surface side on the fourth side surface side;
the third extended line and the fourth extended line are extended from the second side surface side on the fourth side surface side; and
an end portion of the fourth extended line on the second main surface side is on the second side surface side on the fourth side surface side.

10. The coil component according to claim 1, wherein
when the first side surface and the second side surface face each other, and a side surface close to the first extended line is defined as a third side surface and a side surface close to the second extended line is defined as a fourth side surface;
the first extended line is extended from the first side surface side on the fourth side surface side;
the second extended line is extended from the first side surface side on the third side surface side, and an end portion of the second extended line on the second main surface side is on the first side surface side on the fourth side surface side;
the third extended line is extended from the second side surface side on the fourth side surface side; and
the fourth extended line is extended from the second side surface side on the third side surface side, and an end portion of the fourth extended line on the second main surface side is on the second side surface side on the fourth side surface side.

11. The coil component according to claim 1, wherein the first coil and the second coil include a metal plate or a metal wire.

12. The coil component according to claim 1, wherein the first coil and the second coil have a rectangular or substantially rectangular opening.

13. A filter circuit comprising:
the coil component according to claim 1; and
a capacitor electrically connected to the second extended line and the fourth extended line of the coil component.

14. The filter circuit according to claim 13, wherein the first coil and the second coil are closer to the first main surface than to the second main surface inside the housing.

15. The filter circuit according to claim 14, wherein the first coil and the second coil are closer to the first main surface side than to an intermediate position located between the first main surface and the second main surface.

16. The filter circuit according to claim 13, wherein the second extended line and the fourth extended line extend up to the second main surface.

17. The filter circuit according to claim 13, further comprising a connector provided on the second main surface to electrically connect the second extended line and the fourth extended line.

18. The filter circuit according to claim 13, wherein
when the first side surface and the second side surface face each other, and a side surface closest to the first extended line is defined as a third side surface and a side surface closest to the second extended line is defined as a fourth side surface;
the first extended line and the second extended line are extended from an intermediate portion of the first side surface located between the third side surface and the fourth side surface; and
the third extended line and the fourth extended line are extended from an intermediate portion of the second side surface located between the third side surface and the fourth side surface.

19. The filter circuit according to claim 18, wherein
an end portion of the second extended line on the second main surface side is located in the intermediate portion of the first side surface located between the third side surface and the fourth side surface; and
an end portion of the fourth extended line on the second main surface side is located in the intermediate portion of the second side surface located between the third side surface and the fourth side surface.

20. The filter circuit according to claim 18, wherein
an end portion of the second extended line on the second main surface side is on the first side surface side on the fourth side surface side; and
an end portion of the fourth extended line on the second main surface side is on the second side surface side on the fourth side surface side.
